(19) United States
(12) Patent Application Publication
(10) Pub. No.: US 2016/0005986 A1
(43) Pub. Date: Jan. 7, 2016

(54) SOLAR CELL AND METHOD OF MANUFACTURING THE SAME

(71) Applicant: National Cheng Kung University, Tainan City (TW)

(72) Inventors: Tzung-Fang Guo, Tainan City (TW); Chao-Yu Chen, Tainan City (TW)

(21) Appl. No.: 14/534,560

(22) Filed: Nov. 6, 2014

(30) Foreign Application Priority Data
Jul. 2, 2014 (TW) 103122911

(51) Int. Cl. H01L 51/42; H01L 31/032; H01L 51/00; H01L 51/44

(52) U.S. Cl. CPC H01L 51/426; H01L 51/44; H01L 31/032; H01L 51/0077; H01L 2251/303; H01L 2031/0344

(57) ABSTRACT

A solar cell is provided, and has an organic light-absorbing layer having a perovskite structure, and a hole transport layer disposed on a first surface of the organic light-absorbing layer. The hole transport layer is made of a nickel oxide. A method of manufacturing a solar cell is provided, and has the steps of (1) providing a hole transport layer which is made of a nickel oxide; (2) forming an organic light-absorbing layer having a perovskite structure, which has a first surface on which the hole transporting layer is disposed, and a second surface opposite to the first surface; and (3) forming an electron transport layer on the second surface of the organic light-absorbing layer.

### CROSS REFERENCE TO RELATED APPLICATIONS

This application claims the priority of Taiwan Patent Application No. 103122911, filed on Jul. 2, 2014, the disclosure of which is incorporated herein by reference. This invention is partly disclosed in a thesis entitled “Nickel Oxide Electrode Interlayer in CH₃NH₃PbI₃ Perovskite/PCBM Planar-Heterojunction Hybrid Solar Cells” on Mar. 31, 2014 completed by Jun-Yuan Jeng, Kuo-Cheng Chen, Tsung-Yu Chiang, Pei-Ying Lin, Tzung-Da Tsai, Yun-Chorng Chang, Tzung-Fang Guo, Peter Chen, Ten-Chin Wen, and Yao-Jane Hsu, and another thesis entitled “p-type Mesoscopic Nickel Oxide/Organometallic Perovskite Heterojunction Solar Cells” on Apr. 23, 2014 completed by Kuo-Chin Wang, Jun-Yuan Jeng, Po-Shen Shen, Yu-Cheng Chang, Eric Wei-Guang Diau, Cheng-Hung Tsai, Tzu-Yang Chao, Hsu-Cheng Hsu, Pei-Ying Lin, Peter Chen, Tzung-Fang Guo, and Ten-Chin Wen.

### FIELD OF THE INVENTION

The present invention relates to a solar cell, and more particularly to an organic solar cell having a hole transport layer made of a metal oxide and a method of manufacturing the same.

### BACKGROUND OF THE INVENTION

Currently, solar cells are one of the known environmentally friendly power supplies. In the case of energy shortages in recent years, a variety of new solar cells having high-efficiency are developed actively.

Dye-sensitized solar cells (DSSC) belong to a new type of solar cell. Compared with silicon-based solar cells, the materials of DSSC are cheaper, and the clean room is not necessary during production. Thus, DSSC is considered to have the potential for development and application. DSSC has been developed to use an organic-inorganic hybrid perovskite crystalline material, methylammonium lead iodide (CH₃NH₃PbI₃), as a dye-sensitized light-absorbing layer, and organic polymers including (Poly (3,4-ethylenedioxythiophene): poly(styrene-sulfonate) (PEDOT: PSS) as a hole transport layer to prepare a solid state DSSC. The perovskite material has the advantages of low cost and easy acquisition, and if coordinating with different charge transport layers, the perovskite material may be applied to the flexible substrate. In addition, the light-to-electricity power conversion efficiency of DSSC has even been able to exceed the expensive silicon-based solar cells in current studies.

However, in the perovskite solar cell, an organic polymer, PEDOT: PSS, usually correspondingly used as a hole transport layer, has a material stability problem. Considering that solar cells are always running for extended periods of time, this defect in particular needs to be improved upon.

Therefore, it is necessary to provide a solar cell having a hole transport layer made of an inorganic compound for improving material stability to solve the problems existing in the conventional technology, as described above.

### SUMMARY OF THE INVENTION

The primary object of the present invention is to provide a solar cell which comprises an organic light-absorbing layer having a perovskite structure, and a hole transport layer made of a metal oxide, in order to improve the material and structural stability of the solar cell. Furthermore, compared with organic polymers, inorganic metal oxides are easily prepared or produced, and therefore the complexity of overall process for manufacturing the solar cell is reduced.

The secondary object of the present invention is to provide a method of manufacturing a solar cell by using the above mentioned metal oxide which is easily obtained for the purposes of simplifying the manufacturing process, and reducing costs.

To achieve the above objects, the present invention provides a solar cell which comprises an organic light-absorbing layer having a perovskite structure, and a hole transport layer disposed on a first surface of the organic light-absorbing layer, wherein the hole transport layer is made of a nickel oxide.

In one embodiment of the present invention, the nickel oxide has a planar structure, and is selected from NiO, Ni₂O₃ or a composite thereof.

In one embodiment of the present invention, the organic light-absorbing layer is an organolead iodide compound having the chemical formula CH₃NH₃PbI₃.

In one embodiment of the present invention, the organic light-absorbing layer further comprises a porous nanocrystalline nickel oxide, so that the organic light-absorbing layer has a heterojunction.

In one embodiment of the present invention, the solar cell further comprises an electron transport layer disposed on a second surface of the organic light-absorbing layer, wherein the second surface is opposite to the first surface.

In one embodiment of the present invention, the material of the electron transporting layer is a metal oxide.

In one embodiment of the present invention, the metal oxide is zinc oxide.

Furthermore, the present invention provides a method of manufacturing a solar cell, comprising the steps of; (1) providing a hole transport layer, wherein the hole transport layer being made of a nickel oxide; (2) forming an organic light-absorbing layer having a perovskite structure, wherein the organic light-absorbing layer has a first surface and a second surface opposite to the first surface, and the hole transport layer is formed on the first surface; and (3) forming an electron transport layer on the second surface of the light-absorbing layer.

In one embodiment of the present invention, the step (1) is carried out by coating the nickel oxide on a transparent electrode to form the hole transport layer.

In one embodiment of the present invention, the step (2) of forming the organic light-absorbing layer further comprises a step of forming a porous nanocrystalline nickel oxide, so that the organic light-absorbing layer has a heterojunction.

### DESCRIPTION OF THE DRAWINGS

FIG. 1 is a schematic view for showing the solar cell according to the first embodiment of the present invention.

FIG. 2 is a detailed view for showing the organic light-absorbing layer of the solar cell according to the first embodiment of the present invention.

### DETAILED DESCRIPTION OF THE PREFERRED EMBODIMENTS

The structure and the technical means adopted by the present invention to achieve the above and other objects can be best understood by referring to the following detailed description of the preferred embodiments and the accompanying drawings. Furthermore, directional terms described by the present invention, such as upper, lower, front, back, left, right, inner, outer, side, longitudinal/vertical, transverse/horizontal, etc., are only directions by referring to the accompanying drawings, and thus the used directional terms are used to describe and understand the present invention, but the present invention is not limited thereto.

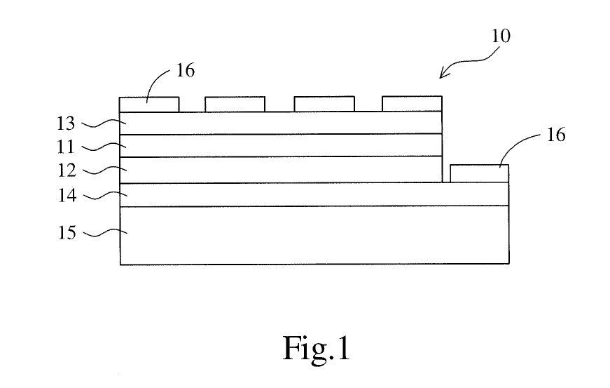

First, please refer to FIG. 1; a solar cell 10 according to a first embodiment of the present invention is illustrated, and includes an organic light-absorbing layer 11 having a perovskite structure, and a hole transport layer 12 disposed on a first surface of the organic light-absorbing layer 11, wherein the hole transport layer 12 is made of a nickel oxide, represented by NiOₓ meaning the nickel has a different valence number, such as NiO, Ni₂O₃ or a composite thereof. Since the nickel oxide has a high work function, it is possible to improve the open-circuit voltage of the device. Preferably, the nickel oxide has a planar structure. The organic light-absorbing layer 11 having the perovskite structure may be, for example, an organolead iodide compound having the chemical formula CH₃NH₃PbI₃. The solar cell 10 according to the first embodiment of the present invention may further comprise an electron transport layer 13 disposed on a second surface of the organic light-absorbing layer 11, wherein the second surface is opposite to the first surface. The electron transport layer 13 is made of a metal oxide which is generally applied to a dye-sensitized solar cell as being the electron transport layer, zinc oxide (ZnO) for example, and is not limited thereto. In addition, the solar cell 10 in accordance with the requirements of practical use may further include a transparent electrode 14, a substrate 15, and a metallic electrode 16. The transparent electrode layer 14 may be, for example, indium tin oxide (ITO) film. The substrate 15 may be a transparent glass plate, a plastic plate or a flexible polymer substrate. The metallic electrode 16 may be, for example, an aluminum electrode, but is not limited thereto. Sunlight can pass through the transparent electrode layer 14 and the substrate 15, and then enter into the solar cell 10. The voltage trends are generated from the electron and hole after carrying out the light-to-electricity power conversion, and then a current loop is switched on via the metallic electrode 16.

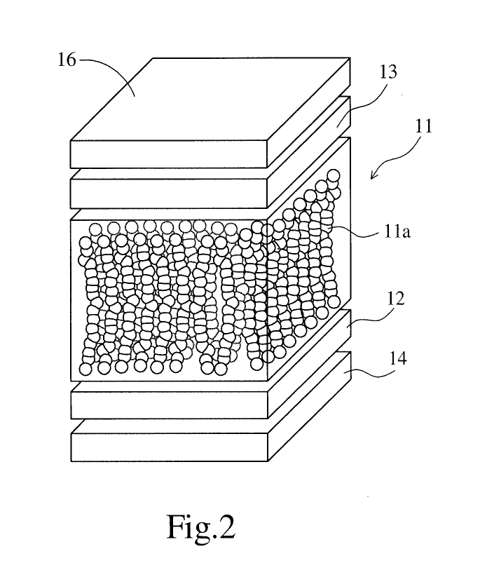

Furthermore, as shown in FIG. 2, the organic light-absorbing layer 11 in the first embodiment of the present invention may further comprise a porous nanocrystalline nickel oxide 11a, so that the organic light-absorbing layer 11 has a heterojunction. Similarly, the solar cell 10 includes the transparent electrode layer 14, the substrate 15, and the metallic electrode 16 on the first surface and the second surface of the organic light-absorbing layer 11. The transparent electrode layer 14 may be, for example, indium tin oxide (ITO) film. The substrate 15 may be a transparent glass plate, a plastic plate or a flexible polymer substrate. The metallic electrode 16 may be, for example, an aluminum electrode, but is not limited thereto.

The second embodiment of the present invention is to provide a method of manufacturing a solar cell 10, comprising the steps of: (1) providing a hole transport layer 12, wherein the hole transport layer 12 is made of a nickel oxide; (2) forming an organic light-absorbing layer 11 having a perovskite structure, which has a first surface and a second surface, wherein the second surface is opposite to the first surface, and the hole transport layer 12 is disposed on the first line on one surface; and (3) forming an electron transport layer 13 on the second surface of the organic light-absorbing layer 11.

In the step (1), the hole transport payer 12 is formed by, for example, spin-coating a nickel oxide solution on a transparent electrode layer 14, and then heating. Preferably, the hole transport payer 12 is formed by spin-coating at 4000 rpm for 90 seconds, and then heating at 300° C. to anneal for 60 minutes in the atmosphere.

Next, in the step (2), the hole transport layer 12 is disposed on the first surface of the organic light-absorbing layer 11. The material of the organic light-absorbing layer is, for example, an organolead iodide compound with the chemical formula CH₃NH₃PbI₃. The electron transport layer 13 is made of a metal oxide which is generally applied to a dye-sensitized solar cell as being the electron transport layer, zinc oxide (ZnO) for example, and is not limited thereto. The step (2) of forming the organic light-absorbing layer 11 may further comprise a step of forming a porous nanocrystalline nickel oxide so that the organic light-absorbing layer 11 has a heterojunction. The porous structure can be prepared by the following sub-steps:

Preparing a solution with 1M lead iodide (PbI₂) in N,N-dimethylformamide, applying the solution to a nanocrystalline nickel oxide film at 6500 rpm for 5 seconds, and then annealing at 70° C. for 30 minutes. After cooling to room temperature, the film is immersed into a propanol solution containing 10 mg/mL of methylammonium iodide (CH₃NH₃l) for 40 seconds, and then annealed again at 70° C. for 30 minutes to form the porous nanocrystalline nickel oxide. The NiOₓ at this time is a composite of NiO and Ni₂O₃.

In order to verify the power conversion efficiency (PCE) of the solar cell provided in the present invention, a hole transport layer (HTL) made of PEDOT: PSS as a control group has been tested, and the statistical data is shown in the following table 1.

TABLE 1

| | open-circuit | |
|---|---|---|
| HTL/Organic light-absorbing layer | voltage (V) | PCE (%) |
| PEDOT:PSS/CH₃NH₃Pbl₃ | 0.62 | 3.9 |
| NiOₓ/CH₃NH₃Pbl₃ | 0.92 | 7.8 |

In this test, the hole transport layer of PEDOT: PSS and nickel oxide were prepared by spin-coating on the surface of an organic light-absorbing layer of CH₃NH₃PbI₃ having a perovskite structure with a rotating speed of 9500 rpm. The other side of the organic light-absorbing layer is an electron transport layer made of a fullerene derivative, [6,6]-phenyl C61-butyric acid methyl ester (DCBM).

From Table 1, the PCE has a substantial upgrade when the hole transport layer is made of NiOₓ according to the solar cell of the present invention. As shown in the experimental results, using nickel oxide as the material of the hole transport layer of the solar cell makes the PCE raise to 7.8%, whereas when using the conventional organic polymer as the hole transport layer material the PCE only reaches 3.9%.

Unlike conventional techniques, the solar cell and the method of manufacturing the solar cell according to the present invention applies a nickel oxide as the material for the hole transport layer, and thus is relatively simple in its structure and manufacture. It improves the material and structural stability of the solar cell, and maintains a certain level of light-to-electricity power conversion efficiency. In addition, if further using a metal oxide (such as zinc oxide) as the electron transport layer on the other side of the light-absorbing layer, the overall structural stability is further enhanced, the manufacturing process is simplified, and the costs are reduced. It shows further superiority when operating for an extended time. In addition, the solar cell according to the present invention, which is applicable to the flexible substrate, makes it more competitive.

The present invention has been described with preferred embodiments thereof and it is understood that many changes and modifications to the described embodiments can be carried out without departing from the scope and the spirit of the invention that is intended to be limited only by the appended claims.

What is claimed is:

1. A solar cell, comprising:
an organic light-absorbing layer having a perovskite structure; and
a hole transport layer disposed on a first surface of the organic light-absorbing layer, wherein the hole transport layer is made of a nickel oxide.

2. The solar cell according to claim 1, wherein the nickel oxide has a planar structure, and is selected from NiO, Ni₂O₃ or a composite thereof.

3. The solar cell according to claim 1, wherein the organic light-absorbing layer is an organolead iodide compound having a chemical formula CH₃NH₃PbI₃.

4. The solar cell according to claim 1, wherein the organic light-absorbing layer further comprises a porous nanocrystalline nickel oxide, so that the organic light-absorbing layer has a heterojunction.

5. The solar cell according to claim 1, further comprising an electron transport layer disposed on a second surface of the organic light-absorbing layer, wherein the second surface is opposite to the first surface.

6. The solar cell according to claim 5, wherein the electron transport layer is made of a metal oxide.

7. The solar cell according to claim 6, wherein the metal oxide is zinc oxide.

8. A method of manufacturing a solar cell, comprising steps of:
(1) providing a hole transport layer, wherein the hole transport layer is made of a nickel oxide;
(2) forming an organic light-absorbing layer having a perovskite structure, wherein the organic light-absorbing layer has a first surface and a second surface opposite to the first surface, and the hole transport layer is formed on the first surface; and
(3) forming an electron transport layer on the second surface of the light-absorbing layer.

9. The method according to claim 8, wherein the step (1) is carried out by coating the nickel oxide on a transparent electrode layer to form the hole transport layer.

10. The method according to claim 8, wherein the organic light-absorbing layer is an organolead iodide compound having a chemical formula CH₃NH₃PbI₃.

11. The method according to claim 8, wherein the material of the electron transporting layer is a metal oxide.

12. The method according to claim 11, wherein the metal oxide is zinc oxide.

13. The method according to claim 8, wherein the step (2) of forming the organic light-absorbing layer further comprises a step of forming a porous nanocrystalline nickel oxide, so that the organic light-absorbing layer has a heterojunction.
